(19) United States
(12) Patent Application Publication
(10) Pub. No.: US 2012/0248570 A1
(43) Pub. Date: Oct. 4, 2012

(54) ON CHIP INTEGRATED INDUCTOR

(75) Inventors: Dusan Golubovic, Heverlee (BE); Kyriaki Fotopoulou, Brussels (BE)

(73) Assignee: NXP B.V., Eindhoven (NL)

(21) Appl. No.: 13/513,834

(22) PCT Filed: Dec. 14, 2010
(86) PCT No.: PCT/IB10/55811

§ 371 Date: Jun. 4, 2012

(30) Foreign Application Priority Data
Dec. 17, 2009 (EP) 09179745.6

(51) Int. Cl. H01L 29/82; H01L 21/02

(52) U.S. Cl. 257/531; 438/3; 257/E29.323; 257/E21.002

(57) ABSTRACT

A semiconductor chip has an integrated inductor, manufactured during back end of line processing. In particular, a loop (30) is formed in a metallization layer and a central region (32) of magnetic material is provided within the loop. The size of the central region is controlled so that it includes no more than five magnetic domains to achieve the desired properties.

The invention relates to an inductor integrated in a semiconductor chip and a method for its manufacture.

Inductors are important elements of integrated circuits in a wide and diverse range of applications. For example, inductors are used in signal processing circuits such as high-pass filters, resonant tank circuits and Butterworth filters in communication systems. Additional applications include impedance matching network topologies in radio frequency (RF) transceiver circuits. Efficient integrated transformers for dc/dc converters in hybrid electric vehicles also require integrated micro-coils. In inductive power transfer systems for radio frequency identification (RFID) devices and embedded biomedical implants integrated coils are key elements. Micro electro-mechanical systems (MEMS) resonators and magnetic sensors also require high quality integrated inductors.

Ideally, inductors should be integrated with system electronics at a system design level. However, traditionally inductors are large auxiliary components which are very difficult to miniaturise. Attempts have been made to eliminate inductors in communication systems by simulating their action by active element. However, this approach can be unsuccessful as it introduces more parasitics and often generates more noise than actual inductors.

When unable to eliminate inductors designers use integrated two-dimensional spiral inductors that are fabricated on the same substrate as the integrated circuits to which they are coupled. Although such inductors can be manufactured by conventional integrated circuit manufacturing, they typically suffer from low inductance, low quality factor and typically consume a large share of surface area.

It would therefore be advantageous to integrate the manufacturing of an inductor with the manufacture of an integrated circuit in an improved way. There is a particular need to fabricate inductors for high frequency applications.

Integrated circuit manufacture is a very advanced technology. The process steps can be divided into the front end of line (FEOL) and the back end of line (BEOL). The front end of line is the set of process steps up to the first metallization layer, and the back end of line is the remainder of the steps. The front end of line manufactures a wide variety of active and passive semiconductor devices on a chip; the back end of line is used to manufacture interconnects and contacts. Increasingly, more than one level of interconnect may be used.

According to the invention, there is provided a method of making an inductor on a chip according to claim 1.

The invention exploits the properties of micrometre or sub-micrometre magnetic elements. They have a higher ferromagnetic resonant frequency compared with their bulk counterparts, so they can be used in a broader frequency range, typically extending into the GHz region. The magnetic permeability is increased compared to the bulk values, and the dissipative part of the permeability reduced. Noise is also reduced.

For these reason, very small magnetic elements are very well suited to providing enhanced inductances on a chip.

The inductances can easily be manufactured in a way compatible with conventional back end processing. There is no need for any changes to manufacture up to the metallization layer used to form the loop.

The invention also relates to a semiconductor chip with an inductor according to claim 9.

For a better understanding of the invention, embodiments will be described, purely by way of example, with reference to the accompanying drawings, in which

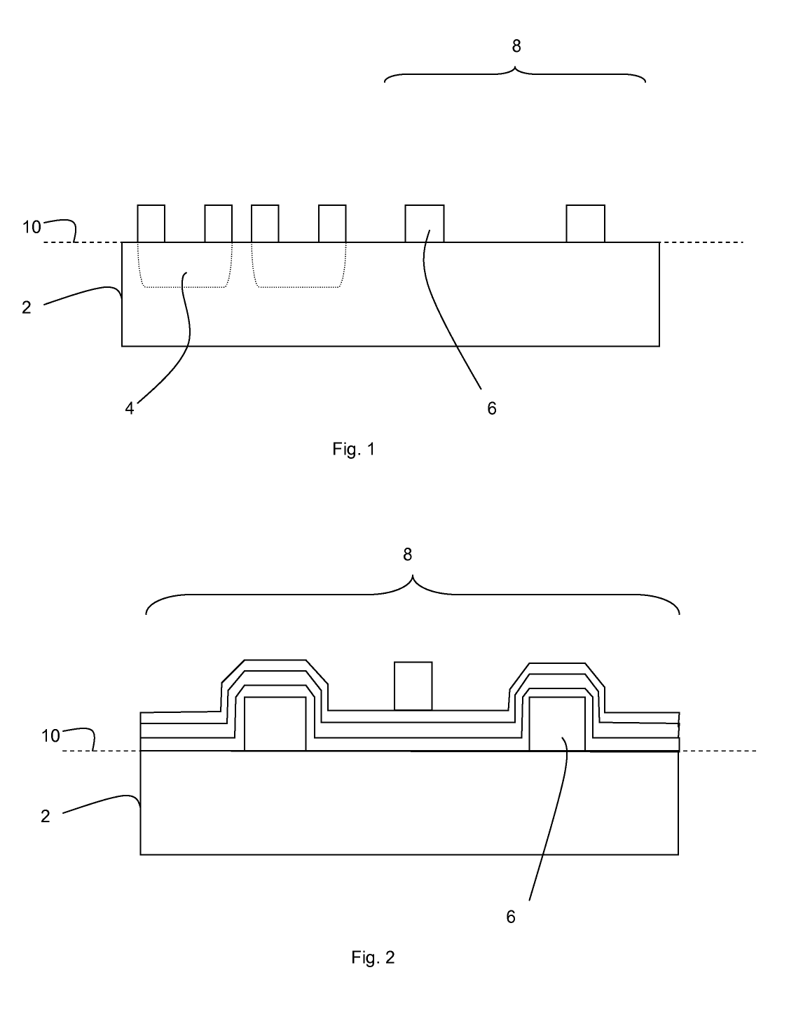

FIG. 1 shows in side view a first stage in the manufacture of an embodiment of the invention;

FIG. 2 shows in side view a second stage in the manufacture of the embodiment;

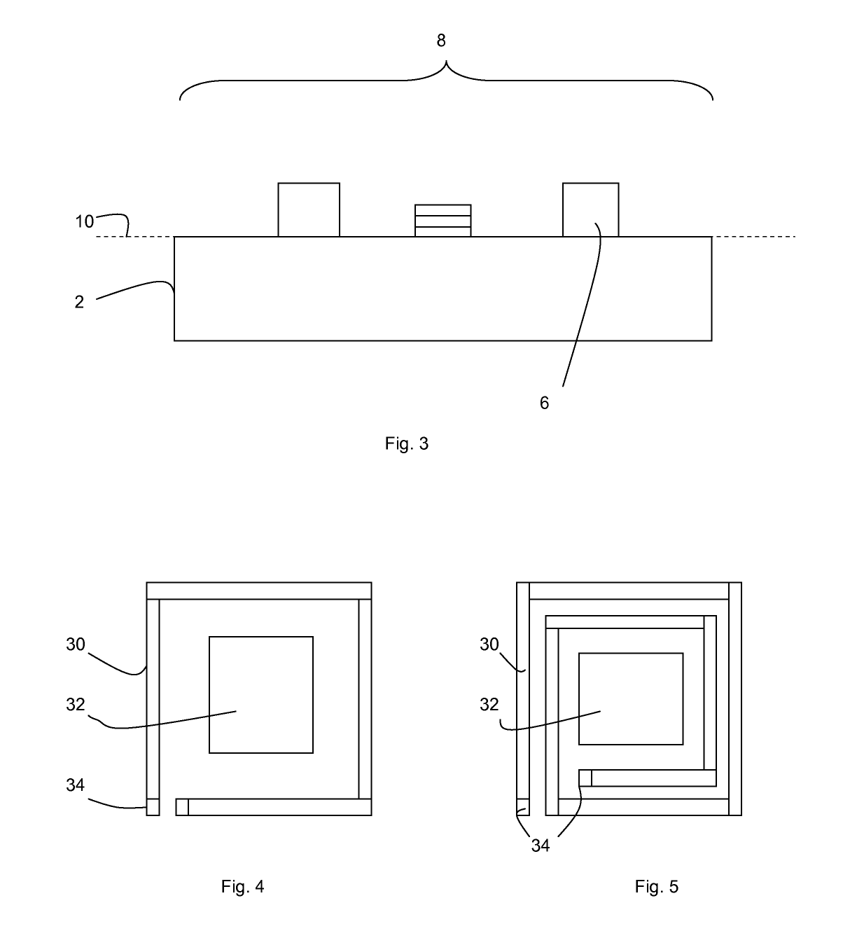

FIG. 3 shows in side view a third stage in the manufacture of the embodiment;

FIG. 4 shows in top view the stage shown in FIG. 3; and

FIG. 5 shows a top view of an alternative layout; and

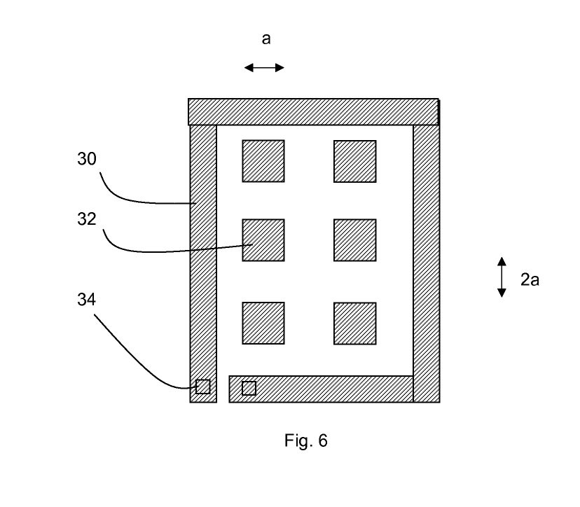

FIG. 6 shows a top view of a further alternative layout.

The figures are schematic and not to scale. In particular, the vertical direction in the side views is greatly exaggerated.

Referring to FIG. 1, an integrated circuit 2 is manufactured to the end of the FEOL to have a plurality of semiconductor devices 4 and a metallization layer 6. In the example, the metallization layer 6 is of Al.

The metallization layer is patterned as usual in regions of the integrated circuit 2 with a semiconductor device and in the region 8 for forming an inductor the metallization layer 6 is patterned to form a loop 30 as illustrated in FIG. 3. The loop is in the plane 10 of the integrated circuit, the plane being indicated in FIG. 1.

Then, a refractory metal layer 12 is deposited over the full surface of the semiconductor device, followed by a magnetic thin film 14 and a protection layer 16. The functions of these layers are described below. The refractory metal layer 12 and magnetic thin film 14 may in particular be deposited by a sputtering process.

A photoresist layer 18 is then deposited and patterned to leave photoresist only on a magnetic element 32 at the centre of the loop, resulting in the arrangement shown in FIG. 1.

The photoresist is then used as a mask in a Chlorine based reactive ion etch process which leaves the triple layer structure of refractory metal layer 12, magnetic thin film 14 and protection layer 16 in the magnetic element 32 in the centre of the loop. The photoresist is then removed.

The size of the magnetic element 32 is chosen to be small, to allow the loop 30 and magnetic core constituted by the magnetic element of the magnetic film to have desirable properties, in particular to operate at high frequencies. The physical considerations behind this will now be discussed.

It is known that when a magnetic material is subjected to a magnetic field oscillating at frequency ω, its response is described by a complex magnetic permeability χ(ω)=χ_{M}(ω)−jχ_{D}(ω) where j is \sqrt{−1}. χ_{M}(ω) governs the magnetic response of the medium, whereas χ_{D}(ω) shows the losses at a frequency ω (when ω→0 then χ_{D}(ω)→0.

In case of bulk magnetic materials, the complex permeability χ (ω) is determined by the intrinsic material properties. On the other hand, the complex permeability of thin magnetic films already significantly differs compared to a bulk specimen with the same composition. Furthermore, by introducing lateral dimensions constraints the properties of a magnetic material can be substantially altered compared to the original bulk material, as well as to thin magnetic films. These changes in the magnetic properties come about due to a substantial modification in magnetic ordering caused by reduced dimensionality.

The general inductive properties of thin current loops are known from textbooks such as S. Ramo, J. R. Whinnery and T. VanDuzer, Fields and Waves in Communication Electronics, John Wiley & Sons, Inc. Third Edition, 1994 and W. R. Smythe, Static and Dynamic Electricity, McGraw-Hill Book Company, Second Edition, 1950.

Integrating a suitable core of magnetic film into the loop can act as a flux-amplifying component. By reducing flux leakage the effective inductance of the coil will increase while the unwanted Ohmic losses will be reduced achieving a high quality factor Q defined as:

$$Q ( ω ) = \frac{ω L}{R}$$

A suitable magnetic material used in on-chip RF integrated inductors must accordingly exhibit high permeability and low magnetic loss in high-frequency range as well as process compatibility with IC processes. Relative permeability (μᵣ) and specific resistivity ρ of a magnetic material are the key parameters. Due to losses in the ferromagnetic material the intrinsic permeability is a complex quantity with a clear frequency dependence defined as:

μᵣ(jω)=μᵣ^{R}−jμᵣ^{I}

where μᵣ^{R} is the real component of the series complex permeability, which represents the magnetic performance and consequently contributes to the inductance L of the integrated coil, while μᵣ^{I} is the imaginary part of the complex permeability and determines the magnetic loss of the material.

At low frequencies for typical ferrite materials μᵣ^{R}is much larger than μᵣ^{I}. For conventional ferrite cores used in transformer applications such as pot core and cylindrical cores it is true that the magnetic losses will increase at high frequencies in the GHz region as ferrite shows a low ferromagnetic resonance frequency f_{M} which is hard to exceed 800 MHz.

Here it needs to be emphasized that for bulk materials both the real and imaginary parts of the complex permeability, as well as ferromagnetic resonance frequency, are governed solely by the material composition. However, when the dimensions of a magnetic structure (thickness, lateral dimensions) become comparable to the average ferromagnetic domain size, the complex permeability becomes strongly dependent on the size, as well. As a result, the size can be used as a efficient means to tailor the relevant properties of a magnetic element.

The high frequency characteristics of permalloy (NiFe) and FeCo thin magnetic films have been investigated by N X Sun et al, IEEE Tran Magnetics, volume 38, number 1, 2002. The −3 dB cut-off frequency is 1.5 GHz. This analysis has been performed on a multi-domain thin film, where magnetic domains are present and magnetic switching occurs through Neel wall rotation. Neel domain walls are in-plane of a thin magnetic film, unlike bulk domain walls (Bloch walls), where magnetization switching occurs out of the film's plane. The presence of Neel walls adds a dumping-like component to the dynamics of the system and limits its cut-off frequency.

As opposed to multi-domain thin magnetic films, magnetic thin films with (sub-) micrometre lateral dimensions are in a single domain state, as formation of a domain wall is energetically less favourable than stray magnetic fields associated with the single domain state. For example, L Giovannini et al, Phys Rev. B, volume 70, 172404, 2004, study the dynamic behaviour of FeNi (permalloy) magnetic disks has been studied. In contrast to the multi-domain films these disks are in the single-domain state, which implies that their dynamics is determined only by spin dynamics and its interactions with lattice, as well as Zeeman and many-body spin and electron interactions. As a result, the cut-off frequency increases dramatically to above 10 GHz.

A significant increase in the cut-off frequency by means of reducing only the lateral dimensions of ferromagnetic thin films has been demonstrated in P. Wang et al, IEEE Tran Magnetics, volume 45, no 1, pp 71-74 (2009), wherein ferromagnetic resonance frequency of a thin permalloy film has been increased from about 8 GHz to 11.5 GHz just by reducing its width from 550 nm to 240 nm.

The inventors have realised that as a result thin-film soft ferromagnetic materials and in particular thin soft magnetic films with (sub-) micrometre lateral dimensions and hence a single magnetic domain (or only a few domains) are suitable for operation in a broad range of frequencies. Thus, the lateral dimension of the or each magnetic element (32) is chosen such that each magnetic element only has a few domains, or preferably exactly one single domain.

The concept works with a wide variety of magnetic materials. Thin film magnetic materials that combine high permeability, good thermal stability, high saturation magnetization, high resistivity, good high-frequency properties, and are silicon process compatible such as are suitable for high frequency inductors.

For ease of processing, relatively well known materials such FeₓNi₁₋ₓ alloy, known as permalloy, may be brought into a single domain state, which allows for high frequency operation m, with thin films of up to 100 nm thickness and lateral dimensions in sub-micrometre regime. As abovementioned, it is possible to exceed 10 GHz-3 dB frequency. Cobalt is a possible alternative.

More advanced materials may be used, for example CoZrTa and Ni—Zn(—Co). These allow for a wider range of possibilities. In particular, it possible using a variety of materials to adjust the properties far more—permalloy is generally used in a form with 80% Ni and 20% Fe and so the bulk properties are fixed. By using ternary materials such as CoZrTa alloy there is a much greater flexibility in the exact alloy composition which allows the exact properties to be tailored to meet requirements. In particular, it may be possible to adjust both the real and imaginary parts of the magnetic permeability with suitable choices of materials, which can in particular allow the degree of loss to be controlled. The choice of such materials may also allow the temperature dependence to be controlled.

Accordingly it is possible to significantly improve f_{M} and reduce μᵣ^{I} with only slightly compromising the overall magnetic permeability of the material μᵣ.

The smaller laterally constrained cores used in the present invention have a number of advantages over bulk materials. Most importantly, the ferromagnetic resonant frequency f_{M} is increased allowing the inductor core to operate into the GHz range. Further, however, the modulus of the magnetic permeability χ (ω) is itself increased, and the dissipative part of the permeability χ_{D}(ω) is decreased.

The noise contribution from Barkhausen noise is also significantly reduced.

For example, a planar 1 μm square central area 32 of magnetic material within and surrounded by a loop with 0.3 μm wide metal lines raises the inductance of the loop from about 1 pH to 0.1 nH, a factor of a hundred. This greatly reduces the area to provide inductances on chip with the improved properties discussed above.

The use of the refractory metal layer 12 under the magnetic region has a number of effects. Firstly, it improves the adhesion of the magnetic film to the inter-metal dielectric which forms the surface of the chip 2. Secondly, it acts as a diffusion barrier which may be important if the magnetic film contains fast diffusers, for example in an alloy. Thirdly, the refractory metal layer 12 may set the texture of the subsequently deposited films, which may be used to tailor the magnetic properties. However, the refractory metal layer 12 is not absolutely essential to the operation of the invention and may be omitted if not required.

The protection layer 16 simply protects the magnetic film. For experimental laboratory purposes gold may be used. For commercial integrated circuit manufacture gold is generally not allowed so standard BEOL refractory metals (compounds) such as TiN or TaN may be used.

The term “loop” does not imply that the loop needs to be a closed loop. See the possible alternative arrangements in FIGS. 4 and 5. Note that the loop is not a complete ring since the loop needs to have contacts 34 formed at the ends of it. The loop can be less than a full turn (FIG. 4) or more than a full turn (FIG. 5).

A further alternative arrangement is shown in FIG. 6. In order to ensure that a magnetic material used is in single domain state, instead of one magnetic element a plurality of magnetic elements can be used as shown in FIG. 6. Assuming the lateral dimensions of the squares shown are a, the separation between them should be kept at 2a (or more) so that there is not electromagnetic interaction between them and anti-ferromagnetic ordering sets in. The same applies for circular magnetic elements with radius r, the distance should be 2r.

By using a plurality of magnetic elements the benefits of small magnetic element size can be used even for loops of larger size and larger inductance.

1. A method of making an inductor on a chip, comprising:
manufacturing an integrated circuit chip on a substrate to a step with a metallization layer formed, the integrated circuit chip including a plurality of semiconductor devices;
defining a loop extending in the plane of the chip in the metallization layer;
depositing a layer of magnetic material;
depositing and patterning resist over the layer of magnetic material to define the area of at least one magnetic element within the loop;
etching to remove the magnetic material except where protected by the resist; and
removing the resist to leave the loop in the metallization layer around at least one magnetic element of the magnetic material, the or each magnetic element having lateral dimensions such that includes no more than five magnetic domains.

2. A method according to claim 1 wherein the or each magnetic element includes a single magnetic domain.

3. A method according to claim 1 wherein the lateral dimension of the or each magnetic element is no more than 1 μm.

4. A method according to claim 1, further comprising depositing a refractory metal layer over the surface of the chip after the step of defining a loop and before the step of depositing a layer of magnetic material, wherein the step of etching also removes the refractory metal except where protected by the resist.

5. A method according to claim 1, further comprising depositing a protection layer over the layer of magnetic material, wherein the step of etching also removes the protection layer except where protected by the resist.

6. A method according to claim 1, wherein the step of etching uses a dry chlorine etch.

7. A method according to claim 1, wherein the magnetic material is an alloy of Fe and Ni.

8. A method according to claim 1, wherein the steps of depositing and patterning resist and etching define a plurality of magnetic elements within the loop, the magnetic elements being spaced apart to have a gap between adjacent elements of at least double the largest lateral dimension of each magnetic element.

9. A semiconductor chip, comprising:
a plurality of semiconductor devices formed on a substrate;
a metallization layer over the substrate, the metallization layer including at least one loop forming an inductor; and
a magnetic material formed as at least one magnetic element within the loop, the magnetic element having lateral dimensions such that includes no more than five magnetic domains.

10. A semiconductor chip according to claim 9, wherein the or each magnetic element includes a single magnetic domain.

11. A semiconductor chip according to claim 9, wherein the lateral dimension of the or each magnetic element is no more than 1 μm.

12. A semiconductor chip according to claim 9, further comprising a layer of refractory metal under the magnetic material.

13. A semiconductor chip according to claim 9, further comprising a protection layer above the magnetic material.

14. A semiconductor chip according to claim 9, wherein the magnetic material is an alloy of Fe and Ni.

15. A semiconductor chip according to claim 9, including a plurality of magnetic elements within the loop, the magnetic elements being spaced apart to have a gap between adjacent elements of at least double the largest lateral dimension of each magnetic element.
